(19) United States
(12) Patent Application Publication
(10) Pub. No.: US 2013/0299841 A1
(43) Pub. Date: Nov. 14, 2013

(54) GaN-Based Optocoupler

(71) Applicants: Jan Ranglack, Villach (AT); Gianmauro Pozzovivo, Villach (AT)

(72) Inventors: Jan Ranglack, Villach (AT); Gianmauro Pozzovivo, Villach (AT)

(73) Assignee: INFINEON TECHNOLOGIES AUSTRIA AG, Villach (AT)

(21) Appl. No.: 13/469,270

(22) Filed: May 11, 2012

(51) Int. Cl. H01L 33/32; H01L 33/48

(52) U.S. Cl. 257/76; 257/80; 257/E33.025; 257/E33.076

(57) ABSTRACT

An optocoupler includes a GaN-based photosensor disposed on a substrate and a GaN-based light source disposed on the same substrate as the GaN-based photosensor. A transparent material is interposed between the GaN-based photosensor and the GaN-based light source. The transparent material provides galvanic isolation and forms an optical channel between the GaN-based photosensor and the GaN-based light source.

### BACKGROUND

There are many situations where signals and data preferably are transferred from one device or system to another without making direct ohmic electrical connection. For example, the devices may be at very different voltage levels such as a microprocessor operating at a relatively low voltage and a switching device operating at a relatively high voltage. In such situations the link between the two devices must be isolated to protect the lower-voltage device from overvoltage damage. One conventional approach used to connect such devices is an optocoupler. An optocoupler uses light to transmit signals or data across an electrical barrier which provides excellent galvanic isolation. Optocouplers have two main components: an optical transmitter such as a gallium arsenide LED (light-emitting diode) and an optical receiver such as a photodiode, phototransistor or light-triggered diac. These two components are separated by a transparent barrier which prevents electrical current flow between the two components, but permits light to pass. An optocoupler fabricated using a GaN-based technology with the optical transmitter and the optical receiver formed on the same die is not known.

### SUMMARY

According to an embodiment of an optocoupler, the optocoupler comprises a GaN-based photosensor disposed on a substrate and a GaN-based light source disposed on the same substrate as the GaN-based photosensor. A transparent material is interposed between the GaN-based photosensor and the GaN-based light source. The transparent material provides galvanic isolation and forms an optical channel between the GaN-based photosensor and the GaN-based light source.

According to an embodiment of an electro-optical circuit, the electro-optical circuit comprises an optocoupler including a GaN-based photosensor disposed on a substrate, the GaN-based photosensor having an electrical side and an optical side, and a GaN-based light source disposed on the same substrate as the GaN-based photosensor, the GaN-based light source having an electrical side and an optical side. A transparent galvanic isolation material is interposed between the GaN-based photosensor and the GaN-based light source, and forms an optical channel between the optical sides of the GaN-based photosensor and the GaN-based light source. The electro-optical circuit further comprises an electrical device electrically connected to the electrical side of the GaN-based photosensor.

According to an embodiment of a package, the package comprises an electrically conductive lead frame and an optocoupler. The optocoupler comprises a GaN-based photosensor disposed on a substrate attached to the lead frame, the GaN-based photosensor having an electrical side and an optical side, and a GaN-based light source disposed on the same substrate as the GaN-based photosensor, the GaN-based light source having an electrical side and an optical side. A transparent galvanic isolation material is interposed between the GaN-based photosensor and the GaN-based light source, and forms an optical channel between the optical sides of the GaN-based photosensor and the GaN-based light source. The package further comprises an electrical device electrically connected to the electrical side of the GaN-based photosensor.

Those skilled in the art will recognize additional features and advantages upon reading the following detailed description, and upon viewing the accompanying drawings.

### BRIEF DESCRIPTION OF THE DRAWINGS

The components in the figures are not necessarily to scale, instead emphasis being placed upon illustrating the principles of the invention. Moreover, in the figures, like reference numerals designate corresponding parts. In the drawings:

FIG. 1 illustrates a perspective cross-sectional view of a GaN-based optocoupler connected to an integrated electrical device according to an embodiment.

FIG. 2 illustrates a circuit schematic of a GaN-based optocoupler connected to an electrical device.

FIG. 3 illustrates a perspective cross-sectional view of a GaN-based optocoupler connected to an integrated electrical device according to another embodiment.

FIG. 4 illustrates a perspective cross-sectional view of a GaN-based optocoupler connected to an electrical device on a different die according to an embodiment.

FIG. 5 illustrates a perspective cross-sectional view of a GaN-based optocoupler connected to an electrical device on a different die according to another embodiment.

### DETAILED DESCRIPTION

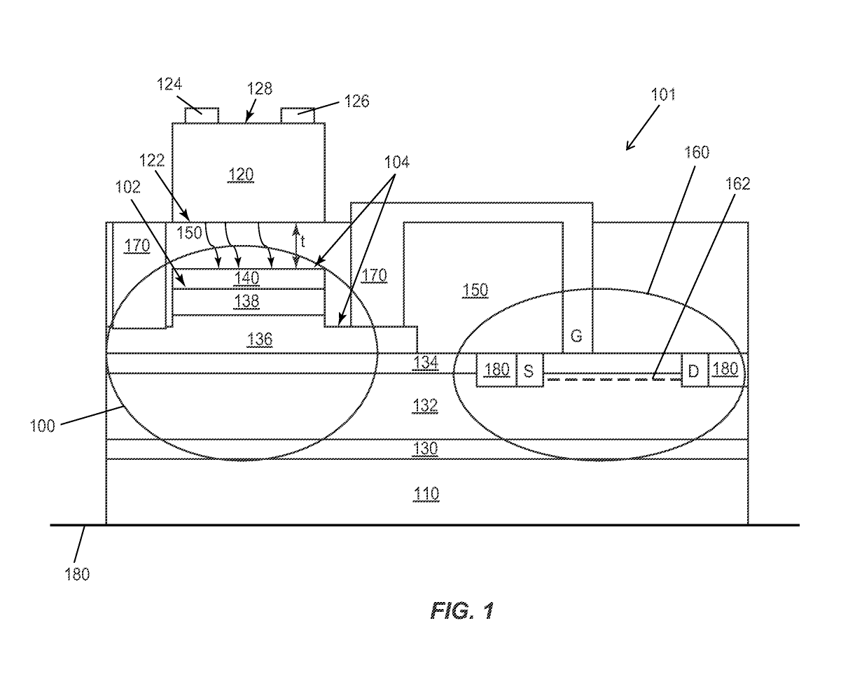

FIG. 1 illustrates a cross-sectional view of an embodiment of an optocoupler which includes a GaN-based photosensor 100 disposed on a substrate 110 and a GaN-based light source 120 disposed on the same substrate 110 as the GaN-based photosensor 100. The term “GaN-based” as used herein means that the corresponding device or component is constructed based on any type of GaN semiconductor technology such as GaN in combination with AlGaN, GaN in combination with InGaN, etc. In each case, the GaN-based photosensor 100 and the GaN-based light source 120 each include GaN as part of the respective structures and are formed on the same substrate 110. For example, a nucleation layer 130 can be formed on the substrate 110. The substrate 110 can be any suitable conductive (doped) or non-conductive (undoped) material, semiconductor or otherwise. In one embodiment, the substrate 110 comprises silicon, silicon dioxide, SiC, carbon or diamond. Other types of semiconductor or non-semiconductor substrates may be used. In the case of a silicon substrate 110, the nucleation layer 130 is AlN. For a SiC substrate 110, the nucleation layer 130 can be GaN or AlGaN. A buffer layer 132 such as a GaN layer is formed on the nucleation layer 130, and a barrier layer 134 such as an AlGaN layer is formed on the buffer layer 132. Other and/or additional GaN-based compound semiconductor layers may be used depending on the device type and construction.

In the region of the GaN-based photosensor 100, an n+GaN layer 136 is provided. A photosensitive layer 138 such as a layer of intrinsic GaN is disposed on the n+GaN layer 136 in the region of the GaN-based photosensor 100, and a p− GaN layer 140 is formed on the photosensitive layer 138. In this embodiment, the n+GaN layer 136, photosensitive layer 138 and p−GaN layer 140 collectively form a photodiode. Other photosensors may be used such as a phototransistor or diac.

In each case, a transparent material 150 is interposed between the GaN-based photosensor 100 and the GaN-based light source 120. The transparent material 150 provides galvanic isolation between the GaN-based photosensor 100 and the GaN-based light source 120. The amount of galvanic isolation is determined at least in part by the type of material and thickness (t) of the material 150 interposed between the GaN-based photosensor 100 and the GaN-based light source 120. In one embodiment, the transparent material 150 is silicon dioxide. In general, the transparent material 150 is thick enough and of a sufficient material to provide the desired galvanic isolation between the GaN-based photosensor 100 and the GaN-based light source 120. In one embodiment, the transparent material 150 provides galvanic isolation up to 10 kV. Other types of transparent and suitably galvanic materials may be used such as diamond-like carbon. In each case, the transparent material 150 also forms an optical channel between the GaN-based photosensor 100 and the GaN-based light source 120.

This way light output from the optical side 122 of the GaN-based light source 120 can readily pass through the transparent material 150 to the optical side 102 of the GaN-based photosensor 100 as indicated by the light energy schematically shown with wavy lines in FIG. 1, while maintaining adequate electrical isolation between the photosensor 100 and light source 120. In one embodiment, the GaN-based photosensor 100 is a photodiode comprising a p-type GaN anode layer 140, an n-type GaN cathode layer 136 and an intrinsic photosensitive GaN layer 138 interposed between the p-type GaN layer 140 and the n-type GaN layer 136. The intrinsic photosensitive GaN layer 138 forms the optical side 102 of the photodiode 100, and the n-type GaN cathode layer 136 and p-type GaN layer 140 form the electrical side 104. In one embodiment, the GaN-based light source 120 is GaN-based light emitting diode (LED) having anode and cathode contacts 124, 126 at the electrical side 128 of the LED 120. The optical side 122 of the LED 120 faces the GaN-based photosensor 100. The LED 120 generates light output at the optical side 122 responsive to inputs at the anode and cathode contacts 124, 126 of the LED 120. The light passes through the intermediary transparent material 150 to the GaN-based photosensor 100, where the light is converted from optical energy by the intrinsic photosensitive GaN layer 138 to electrical energy made available at the n-type GaN cathode layer 136.

An electrical device 160 such as a transistor or a passive device is electrically connected to the electrical side (cathode) 104 of the GaN-based photosensor 100 to form an electro-optical circuit e.g. as shown in FIG. 1. According to the embodiment illustrated in FIG. 1, the electrical device 160 is disposed on the same substrate 110 as the GaN-based photosensor 100 and the GaN-based light source 120 and is a GaN-based electrical device. Particularly according to this embodiment, the GaN-based electrical device is a GaN-based transistor such as a MOSFET (metal oxide semiconductor field effect transistor) or HEMT (high electron mobility transistor) having a gate (G), source (S), drain (D) and channel 162. The gate may or may not be insulated from the underlying channel 162 depending on the type of transistor. The channel 162 is disposed between the source and the drain and controlled by the gate. Also according to this embodiment, the GaN-based photosensor 100 is a GaN-based photodiode having an anode 140 and cathode 136. The cathode 136 of the GaN-based photodiode 100 is electrically connected to the gate of the GaN-based transistor 160 via a wire or other suitable conductor 170 disposed on the common substrate 110. An isolation region 180 such a dielectric insulation region or an implanted region separates the GaN-based photodiode 100 from the source, drain and channel 162 of the GaN-based transistor 160.

Using the opto-electrical capabilities of any suitable GaN-based technology, the transistor and optocoupler can be fabricated on the same die 101 as shown in FIG. 1. The gate of the GaN-based transistor 160 is connected to the cathode 136 of the GaN-based photodiode 100 as described above. When the LED 120 emits light, the photodiode 100 charges the gate capacitance of the transistor 160 to increase the gate-source voltage, turning on the transistor 160. When the transistor 160 is turned off, the photodiode 100 stops charging and the internal discharger switch is automatically closed. This in turn forces the gate to discharge. As a result, the gate-source voltage immediately drops. One advantage of a GaN-based transistor is lower gate charge, yielding a turn-on and turn-off process which is much faster compared to Si technologies. In this way it is possible to drive directly the GaN-based transistor which is integrated on same die 101 as the optocoupler. The die 101 can be included in a package by attaching the die 101 to a lead frame 180 e.g. as shown in FIG. 1. The lead frame 180 provides the necessary electrical connections to the die 101 as is well known in the semiconductor package arts e.g. via bond wires, ribbon connections, etc. The back side of the die 101 can be directly electrically connected to a conductive region of the lead frame 180 if the substrate 110 forms part of the conductive pathway to the electro-optical circuit. Otherwise, the substrate 110 is non-conductive and the back side of the die 101 is attached to the lead frame 180 merely for support and to remove waste heat energy from the die 101.

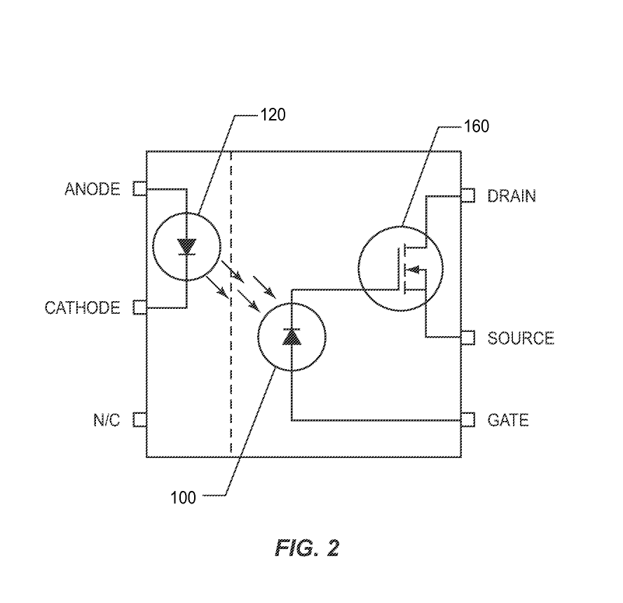

FIG. 2 shows the corresponding circuit schematic, for a six-pin package including the integrated attached to the lead frame 180. The package has one no-connect (N/C) pin. The package further includes anode (Anode) and cathode (Cathode) pins which are connects to the respective anode and cathode contacts 124, 125 of the GaN-based LED 120. The remaining three pins control operation of the GaN-based transistor 160. Particularly, source (Source), drain (Drain) and gate (Gate) pins are provided. The source and drain pins are connected to the source and drain of the transistor 160, respectively. The gate pin is connected to the anode 140 of the GaN-based photodiode, the cathode 136 of which is connected to the gate of the transistor 160 as described above and shown in FIG. 1.

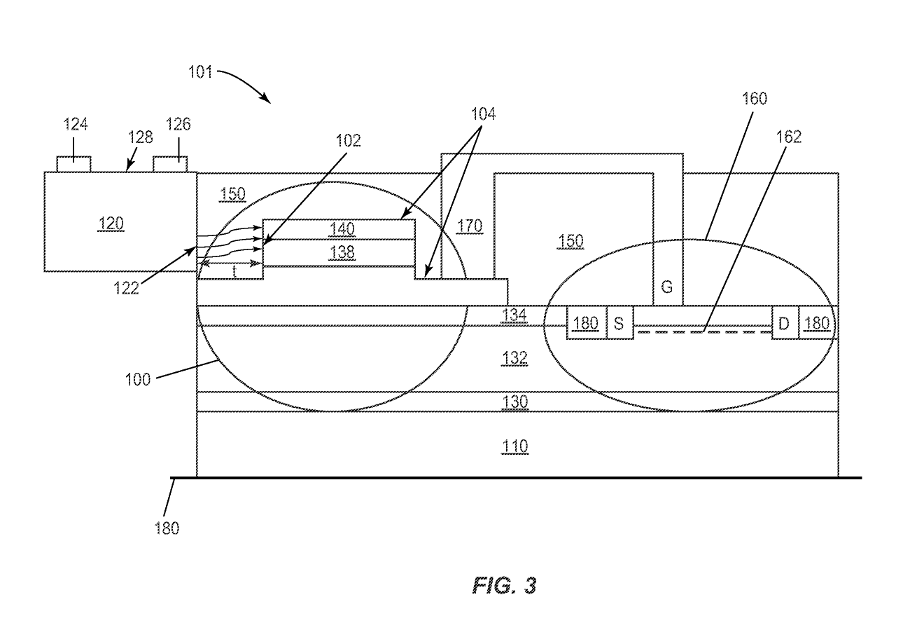

FIG. 3 illustrates a cross-sectional view of another embodiment of a GaN-based optocoupler with an integrated electrical device 160. The embodiment shown in FIG. 3 is similar to the embodiment shown in Figure, however in FIG. 1 the GaN-based light source 120 is point attached to a region of the transparent material 150 covering the top side of the GaN-based photosensor 100 facing away from the substrate 110. In this case, the optical channel is disposed between the GaN-based light source 120 and the top side of the GaN-based photosensor 100. In FIG. 3, the GaN-based light source 120 is point attached to a region of the transparent material 150 covering a sidewall of the GaN-based photosensor 100. In this embodiment, the optical channel is disposed between the GaN-based light source 120 and the sidewall of the GaN-based photosensor 100. In both cases, the electrical device 160 connected to the photosensor 100 is formed on the same substrate 110 as the optocoupler and therefore is based on the same GaN technology as the light source 120 and photosensor 100. The electrical device 160 is integrated with the optocoupler on the same die according to these embodiments.

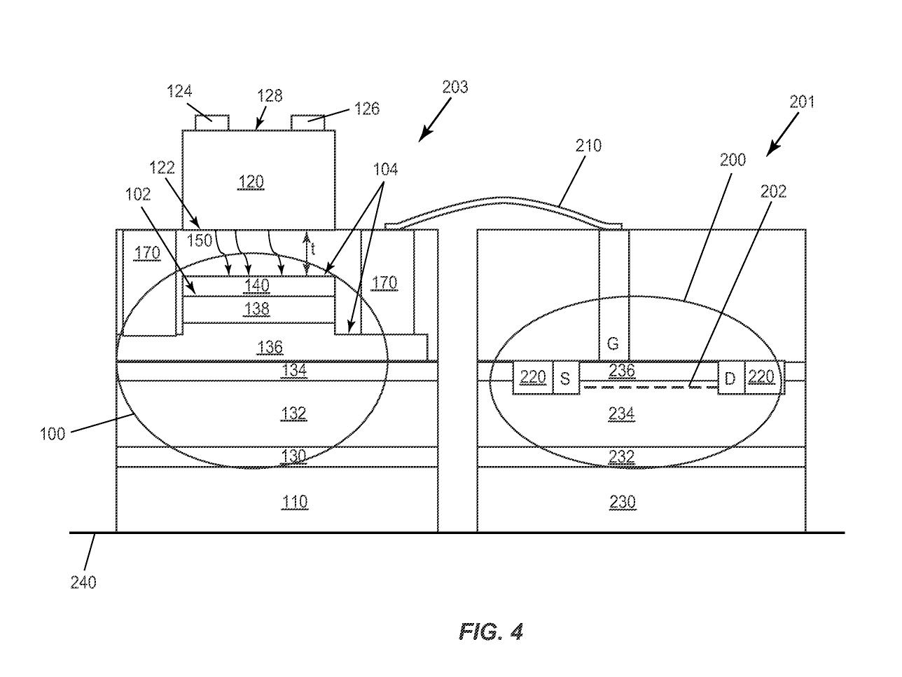

FIG. 4 illustrates a cross-sectional view of an embodiment of a GaN-based optocoupler with a non-integrated electrical device 200. According to this embodiment, the electrical device 200 is fabricated on a separate die 201 than the GaN-based optocoupler. For ease of explanation only, the GaN-based photosensor 100 is shown as a GaN-based photodiode and the non-integrated electrical device 200 is shown as a GaN-based transistor in FIG. 4. The cathode 136 of the GaN-based photodiode 100 is electrically connected to the gate (G) of the GaN-based transistor 200 through a bonding wire or other type of external die electrical connection 210. The gate may or may not be insulated from the underlying channel 202 depending on the type of transistor. The channel 202 is disposed between the source (S) and drain (D) and controlled by the gate. A device isolation region 220 such as a dielectric material or implanted region isolates the transistor 200 from other devices formed on the same die.

The transistor die 201 is constructed from e.g. a nucleation layer 232 such as an AlN layer formed on a substrate 230 separate from the optocoupler substrate 110. A buffer layer 234 such as a GaN layer is formed on the nucleation layer 232 and a barrier layer 236 such as an AlGaN layer is formed on the buffer layer 234. Depending on the device type and construction, other GaN-based compound semiconductor layers may be used to construct the transistor 200. In yet other embodiments, the transistor 200 is based on a III-IV technology other than GaN such as GaAs or SiC, or is based on Si technology e.g. as a MOSFET. The electrical device 200 need not be a transistor, but instead may be a passive device such as a resistor or capacitor. Other photosensors may be used instead of a photodiode such as a phototransistor or diac. In each case, both the optocoupler die 203 and the electrical device die 201 can be included in the same package by attaching each separate die 201, 203 to the same lead frame 240 as shown in FIG. 4. The lead frame 240 is structured in an appropriate manner as is well known in the package semiconductor arts to provide the necessary electrical connections to both the optocoupler die 203 and the electrical device die 201.

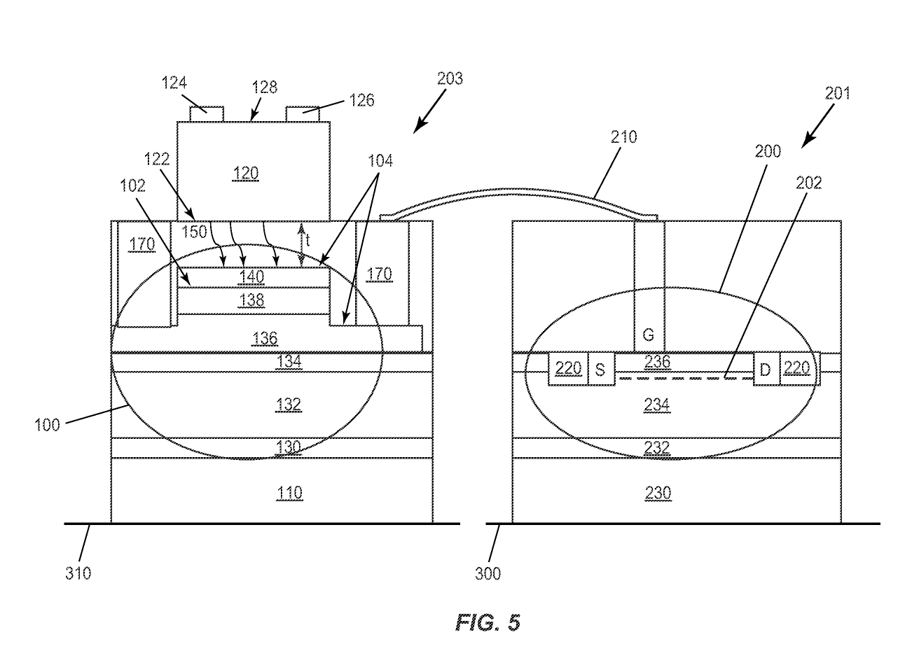

FIG. 5 illustrates a cross-sectional view of an embodiment of a GaN-based optocoupler with a non-integrated electrical device 200 similar to the embodiment shown in FIG. 4, however the non-integrated electrical device die 201 is attached to one lead frame 300 and the GaN-based optocoupler die 203 is attached to a different lead frame 310. The lead frames 300, 310 can be included in the same package or different packages.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. An optocoupler, comprising:
a GaN-based photosensor disposed on a substrate;
a GaN-based light source disposed on the same substrate as the GaN-based photosensor; and
a transparent material interposed between the GaN-based photosensor and the GaN-based light source, the transparent material providing galvanic isolation and forming an optical channel between the GaN-based photosensor and the GaN-based light source.

2. An optocoupler according to claim 1, wherein the GaN-based photosensor is a photodiode comprising a p-type GaN layer, an n-type GaN layer and an intrinsic GaN layer interposed between the p-type GaN layer and the n-type GaN layer.

3. An optocoupler according to claim 1, wherein the GaN-based light source is attached to a region of the transparent material covering a side of the GaN-based photosensor facing away from the substrate.

4. An optocoupler according to claim 1, wherein the GaN-based light source is attached to a region of the transparent material covering a sidewall of the GaN-based photosensor.

5. An optocoupler according to claim 1, wherein the substrate comprises silicon, silicon dioxide, carbon or diamond.

6. An optocoupler according to claim 1, wherein the transparent material comprises silicon dioxide or diamond-like carbon.

7. An optocoupler according to claim 1, wherein the transparent material provides galvanic isolation between the GaN-based photosensor and the GaN-based light source up to 10 kV.

8. An electro-optical circuit, comprising:
an optocoupler comprising:
a GaN-based photosensor disposed on a substrate, the GaN-based photosensor having an electrical side and an optical side;
a GaN-based light source disposed on the same substrate as the GaN-based photosensor, the GaN-based light source having an electrical side and an optical side; and
a transparent galvanic isolation material interposed between the GaN-based photosensor and the GaN-based light source, the transparent galvanic isolation material forming an optical channel between the optical sides of the GaN-based photosensor and the GaN-based light source; and
an electrical device electrically connected to the electrical side of the GaN-based photosensor.

9. An electro-optical circuit according to claim 8, wherein the electrical device is disposed on the same substrate as the GaN-based photosensor and the GaN-based light source, and wherein the electrical device is a GaN-based electrical device.

10. An electro-optical circuit according to claim 9, wherein the GaN-based photosensor is a GaN-based photodiode having an anode and a cathode, wherein the GaN-based electrical device is a GaN-based transistor having a gate, a source, a drain and a channel, the channel disposed between the source and the drain and controlled by the gate, and wherein the cathode of the GaN-based photodiode is electrically connected to the gate of the GaN-based transistor.

11. An electro-optical circuit according to claim 10, further comprising an electrical insulator separating the GaN-based photodiode from the source, drain and channel of the GaN-based transistor.

12. An electro-optical circuit according to claim 8, wherein the electrical device is disposed on a different substrate than the GaN-based photosensor and the GaN-based light source.

13. An electro-optical circuit according to claim 12, wherein the electrical device is based on a semiconductor technology other than GaN.

14. An electro-optical circuit according to claim 8, wherein the GaN-based light source is attached to a region of the transparent galvanic isolation material covering a side of the GaN-based photosensor facing away from the substrate.

15. An electro-optical circuit according to claim 8, wherein the GaN-based light source is attached to a region of the transparent galvanic isolation material covering a sidewall of the GaN-based photosensor.

16. An electro-optical circuit according to claim 8, wherein the transparent galvanic isolation material provides galvanic isolation between the GaN-based photosensor and the GaN-based light source up to 10 kV.

17. A package, comprising:
an electrically conductive lead frame,
an optocoupler comprising:
a GaN-based photosensor disposed on a substrate attached to the lead frame, the GaN-based photosensor having an electrical side and an optical side;
a GaN-based light source disposed on the same substrate as the GaN-based photosensor, the GaN-based light source having an electrical side and an optical side; and
a transparent galvanic isolation material interposed between the GaN-based photosensor and the GaN-based light source, the transparent galvanic isolation material forming an optical channel between the optical sides of the GaN-based photosensor and the GaN-based light source; and
an electrical device electrically connected to the electrical side of the GaN-based photosensor.

18. A package according to claim 17, wherein the electrical device is disposed on a different substrate than the GaN-based photosensor and the GaN-based light source and attached to a different electrically conductive lead frame than the optocoupler.

19. A package according to claim 18, wherein the electrical device is based on a semiconductor technology other than GaN.

20. A package according to claim 17, wherein the electrical device is disposed on the same substrate as the GaN-based photosensor and the GaN-based light source, and wherein the electrical device is a GaN-based electrical device.

21. A package according to claim 20, wherein the GaN-based photosensor is a GaN-based photodiode having an anode and a cathode, wherein the GaN-based electrical device is a GaN-based transistor having a gate, a source, a drain and a channel, the channel disposed between the source and the drain and controlled by the gate, and wherein the cathode of the GaN-based photodiode is electrically connected to the gate of the GaN-based transistor.

22. A package according to claim 21, further comprising an electrical insulator separating the GaN-based photodiode from the source, drain and channel of the GaN-based transistor.
